(19) United States
(12) Patent Application Publication
(10) Pub. No.: US 2009/0085561 A1
(43) Pub. Date: Apr. 2, 2009

(54) METHOD AND APPARATUS FOR TESTING A MAGNETIC HEAD

(75) Inventor: Hiroyuki Kawata, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/333,947

(22) Filed: Dec. 12, 2008

Related U.S. Application Data
(63) Continuation of application No. PCT/JP2006/312498, filed on Jun. 22, 2006.

(51) Int. Cl. G01R 33/12

(52) U.S. Cl. 324/212

(57) ABSTRACT

A testing apparatus for a magnetic head tests electromagnetic conversion characteristics of the magnetic head by causing a magnetic head 10 to fly above a surface of the recording medium 16 and testing recording and playback characteristics of the magnetic head for the recording medium. The testing apparatus includes a setting portion 14 that moves the magnetic head 10 to and supports the magnetic head at a position where the magnetic head 10 is loaded on the recording medium 16 and a position where the magnetic head is withdrawn from the load position; an electromagnetic wave emitting device 30 that emits electromagnetic waves toward the magnetic head; and a detector 20 that is electrically connected to the magnetic head and detects an output signal of the magnetic head. By applying electromagnetic waves from the electromagnetic wave emitting device 30 onto the magnetic head, it is possible to detect the electromagnetic wave durability of the magnetic head 10.

### METHOD AND APPARATUS FOR TESTING A MAGNETIC HEAD

This application is a Continuation of International Application Serial No. PCT/JP2006/312498, filed Jun. 22, 2006.

### TECHNICAL FIELD

The present invention relates to a method and apparatus for testing a magnetic head that are capable of testing the electromagnetic durability of a magnetic head by applying electromagnetic waves to the magnetic head and investigating the characteristics of the magnetic head.

### BACKGROUND ART

A magnetic head used in a magnetic disk apparatus needs to be machined with extremely high precision. Accordingly, evaluation tests are carried out as necessary during the manufacturing process, before assembly of a magnetic disk apparatus, and/or before shipping. FIG. 3 shows the construction of a conventional apparatus that tests the electromagnetic conversion characteristics (i.e., read/write characteristics) of a magnetic head in a state where a slider 10 on which the magnetic head has been formed has been mounted on a head suspension 12.

In this testing apparatus, the head suspension 12 on which the slider 10 has been mounted is set on a setting portion 14, a recording medium 16 is rotationally driven by a driving apparatus 18 and, in a state where the slider 10 has been caused to fly above the surface of the recording medium 16, a signal is recorded on the recording medium 16 by the magnetic head (i.e., the write element). The signal recorded on the recording medium 16 is then converted to a current (voltage) by a read element, and the result of such conversion and noise are detected by a detector 20 to test the characteristics of the magnetic head.

With this conventional testing apparatus, the magnetic head is tested in a state where the magnetic head has been mounted on a head suspension, which is substantially the same state as when a magnetic disk apparatus has been assembled. However, recent magnetic heads are subject to a phenomenon where operation becomes unstable due to the effect of external electric fields (electromagnetic waves). For example, since a TMR element (tunnel magnetoresistive element) or the like used in a read element is structurally susceptible to the effects of external electromagnetic waves, it has become necessary to test the electromagnetic wave durability in addition to the electromagnetic conversion characteristics.
Patent Document 1

Japanese Laid-Open Patent Publication No. H09-16921
Patent Document 2

Japanese Laid-Open Patent Publication No. H11-352171

### DISCLOSURE OF THE INVENTION

A conventional example of an apparatus for testing the effects of external electromagnetic waves on a magnetic disk apparatus is shown in FIG. 4. In this apparatus, a magnetic disk apparatus 30 is disposed inside an electromagnetic wave darkroom 32, the magnetic disk apparatus 30 and a detector 34 are connected by a flat cable 34a, and the characteristics are tested by applying electromagnetic waves to the magnetic disk apparatus 30 inside the electromagnetic wave darkroom 32. This testing apparatus is used as a dedicated apparatus for testing the electromagnetic wave durability and tests magnetic disk apparatuses in an assembled state. Accordingly, there is a problem that only magnetic disk apparatuses that have been assembled can be tested, so that it is not possible to test individual magnetic heads. Also, since the testing of electromagnetic wave durability is a separate process to the process that tests the characteristics of a magnetic head, there is a further problem that testing becomes complex.

It is an object of the present invention to provide a method and apparatus for testing a magnetic head that can test the electromagnetic conversion characteristics (i.e., read/write characteristics) and/or noise characteristics of a head assembly where the magnetic head has been mounted on a head suspension and can also test the electromagnetic wave durability of the magnetic head.

To achieve the stated object, the present invention has the following construction.

A testing apparatus for a magnetic head tests electromagnetic conversion characteristics of the magnetic head by causing the magnetic head to fly above a surface of a recording medium and testing recording and playback characteristics of the magnetic head for the recording medium. The testing apparatus includes: a setting portion that moves the magnetic head to and supports the magnetic head at a position where the magnetic head is loaded on the recording medium and a position where the magnetic head is withdrawn from the load position; an electromagnetic wave emitting device that emits electromagnetic waves toward the magnetic head; and a detector that is electrically connected to the magnetic head and detects an output signal of the magnetic head.

According to this testing apparatus for a magnetic head, it is possible to test the electromagnetic conversion characteristics (i.e., read/write characteristics) of the magnetic head and also test the electromagnetic wave durability of the magnetic head. This apparatus can be favorably used when testing a magnetic head on which a TMR element or the like that has low electromagnetic wave durability has been mounted.

Also, by providing an antenna that focuses the electromagnetic waves of the electromagnetic wave emitting device onto the magnetic head, it is possible to test the electromagnetic wave durability of the magnetic head while efficiently applying electromagnetic waves onto the magnetic head.

Also, by having a testing region that includes the electromagnetic wave emitting device shielded by a shield from external electromagnetic waves, it is possible to carry out testing without fluctuations.

A testing method according to the present invention tests a magnetic head using the testing apparatus described above and is characterized by: supporting the magnetic head using the setting portion; moving the magnetic head to the position that is withdrawn from the load position on the recording medium; emitting electromagnetic waves toward the magnetic head from the electromagnetic wave emitting device at the moved-to position; and testing electromagnetic wave durability of the magnetic head by detecting output noise of the magnetic head during emission of the electromagnetic waves using the detector.

Another testing method according to the present invention tests a magnetic head using the testing apparatus described above and is characterized by: supporting the magnetic head using the setting portion; moving the magnetic head to a load position on the recording medium; emitting electromagnetic waves toward the magnetic head from the electromagnetic wave emitting device at the moved-to position; and testing electromagnetic wave durability of the magnetic head by detecting output noise of the magnetic head during emission of the electromagnetic waves using the detector.

By having the magnetic head supported at a varying flying height from a surface of the recording medium by the setting portion and detecting flying-height-dependent electromagnetic wave durability of the magnetic head, it is possible to even more reliably detect the electromagnetic wave durability of the magnetic head at the position where the magnetic head is loaded on the recording medium.

Also, by emitting electromagnetic waves from the electromagnetic wave emitting device toward the magnetic head while continuously varying the frequency and detecting output noise of the magnetic head using the detector, it is possible to test the electromagnetic wave durability of the magnetic head more favorably.

It is also possible to test electromagnetic wave durability of the magnetic head with a head assembly, where a slider has been mounted on a head suspension, set on the setting portion.

### BRIEF DESCRIPTION OF THE DRAWINGS

FIG. 1 is a diagram useful in showing the construction of a first embodiment of a testing apparatus for a magnetic head.

FIG. 2 is a diagram useful in showing the construction of a second embodiment of a testing apparatus for a magnetic head.

FIG. 3 is a diagram useful in showing the construction of a conventional testing apparatus that tests the characteristics of a magnetic head.

FIG. 4 is a diagram useful in showing the construction of an apparatus that tests the electromagnetic wave durability of a magnetic disk apparatus.

### BEST MODE FOR CARRYING OUT THE INVENTION

### First Embodiment

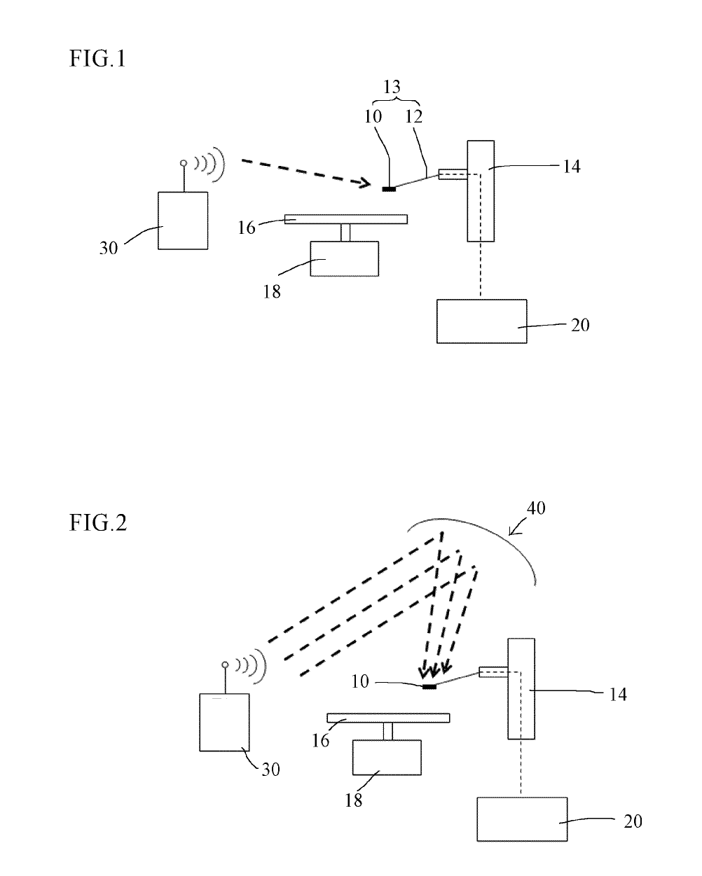

FIG. 1 shows the construction of a first embodiment of a testing apparatus for a magnetic head according to the present invention. The testing apparatus according to the present embodiment is characterized by being capable of testing electromagnetic conversion characteristics (i.e., read/write characteristics) in a state where a magnetic head has been mounted on a head suspension and also of testing the electromagnetic wave durability of the magnetic head.

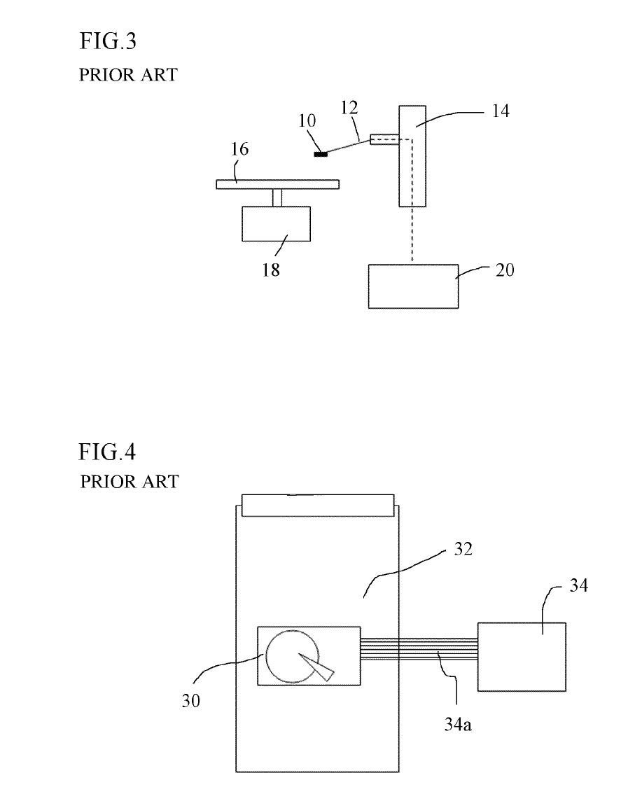

In FIG. 1, the construction of the apparatus for testing the electromagnetic conversion characteristics of a magnetic head is the same as the conventional construction shown in FIG. 3. That is, the apparatus includes a setting portion 14 on which a head assembly 13 where the slider 10 has been mounted on the head suspension 12 is set, a detector 20 that is electrically connected to a magnetic head formed on a slider 10 and detects signals such as the output of the magnetic head and noise, a test recording medium 16 used for read/write tests, and a driving apparatus 18 for the recording medium 16.

The construction of this testing apparatus for a magnetic head according to the present embodiment is characterized by including, in addition to the construction described above, an electromagnetic wave emitting apparatus 30 that emits electromagnetic waves toward the magnetic head. This electromagnetic wave generating apparatus 30 is capable of emitting electromagnetic waves of a predetermined frequency band such as 10 MHz to 100 MHz.

Although there are many conceivable reasons why a magnetic head is somehow affected by electromagnetic waves, one of such reasons is the magnetic head circuit having a capacitance that is affected by external electromagnetic waves (i.e., an electric field or magnetic field).

### Method of Utilizing the Testing Apparatus

According to the testing apparatus for a magnetic head shown in FIG. 1, by attaching the head assembly 13 to the setting portion 14, recording a signal on the recording medium 16, and reading the recorded signal, it is possible to test the electromagnetic conversion characteristics (read/write characteristics) of the magnetic head. The method of testing the electromagnetic conversion characteristics of a magnetic head is the same as with the conventional testing apparatus.

With the testing apparatus of a magnetic head according to the present embodiment, in addition to such tests, it is also possible to test the electromagnetic wave durability of the magnetic head.

One method of testing the electromagnetic wave durability of the magnetic head tests the characteristics of a magnetic head by emitting electromagnetic waves toward the slider 10 from the electromagnetic wave generating apparatus 30 in a state where the slider 10 has been sufficiently separated from the recording medium 16.

Since a magnetic head has a capacitance, the magnetic head suffers from an increase in noise in response to electromagnetic waves of a specific frequency. Accordingly, electromagnetic wave durability tests can be carried out by detecting the output of the read element and/or noise using the detector 20 while continuously changing the frequency of the electromagnetic waves emitted from the electromagnetic wave generating apparatus 30, or changing such frequency in steps of a predetermined frequency.

It is not favorable for a magnetic head to have characteristics whereby there is an increase in noise at a specific frequency when electromagnetic waves are applied to the magnetic head. When designing a magnetic head, a construction that cancels out the capacitance at a predetermined frequency range is designed so that there will be no increase in noise at the specific frequency. However, due to manufacturing fluctuations and the like, it is still possible for noise to increase at a given frequency Therefore by carrying out an electromagnetic wave durability test using the testing apparatus according to the present embodiment, it is possible to detect whether the electromagnetic wave durability of this type of magnetic head is defective.

Another method of testing the electromagnetic wave durability of a magnetic head carries out testing in a state where the slider 10 has been loaded on the recording medium 16. That is, data is recorded and played back on the recording medium 16 with the slider 10 at a flying position that is only slightly separated from the surface of the recording medium 16. In a state where the slider 10 has been loaded on the recording medium 16 with the slider 10 flying at a very low height above the recording medium 16, a capacitance will be produced between the recording medium 16 and the magnetic head.

Accordingly, by emitting the electromagnetic waves from the electromagnetic wave generating apparatus 30 toward the magnetic head in a state where the slider 10 has been loaded on the recording medium 16, it is possible to test the electromagnetic wave durability of a magnetic head in a loaded state. In this state also, by detecting the noise output from the detector 20 while continuously changing the frequency of the electromagnetic waves emitted from the electromagnetic wave generating apparatus 30, it will be possible to test and evaluate the electromagnetic wave durability of the magnetic head having found the phenomenon whereby the noise output increases at a predetermined frequency.

By controlling the setting portion 14 so as to change the gap (the flying height) between the surface of the recording medium 16 and the magnetic head (i.e., the slider 10) when the magnetic head has been loaded on the recording medium 16, it is possible to test how the electromagnetic wave durability varies in accordance with the flying height. Such test results can be utilized when designing a magnetic head and also when designing the slider 10 and the flying height.

Depending on the product, even if there is no problem with electromagnetic wave durability in tests where the magnetic head has not been loaded on the recording medium 16 (i.e., where the magnetic head is sufficiently separated from the recording medium 16), there may still be problems with electromagnetic wave durability when the magnetic head is loaded onto a recording medium. Accordingly, it is effective to test the electromagnetic wave durability of the magnetic head when the magnetic head has been loaded on the recording medium 16.

It should be noted that when testing the electromagnetic conversion characteristics for recording and playing back signals on the recording medium 16 from the magnetic head, it is possible to simultaneously apply electromagnetic waves to the magnetic head and carry out tests. That is, according to this testing method, it is possible to carry out tests into whether read errors occur for the magnetic head both when electromagnetic waves are emitted onto the magnetic head and when electromagnetic waves are not emitted. Since electromagnetic waves that act on the magnetic head can affect the read errors of the magnetic head, such tests will be effective in this case.

Note that although the output of the detector 20 is tested while continuously or discretely changing the frequency of the electromagnetic waves emitted from the electromagnetic wave generating apparatus 30 in the testing method described above, it is also possible to test the electromagnetic wave durability of a magnetic head by emitting electromagnetic waves (that is, white electromagnetic waves) that cover a predetermined frequency range from the electromagnetic wave generating apparatus 30 and detecting the output of the magnetic head using the detector 20. If the impedance of the magnetic head circuit is known in advance, it is possible to carry out a Fourier transformation on the output of the detector 20 and find out whether electromagnetic waves of any frequency emitted from the electromagnetic wave generating apparatus 30 cause noise to be produced.

In this way, according to the testing apparatus for a magnetic head according to the present embodiment, it is possible to test the electromagnetic conversion characteristics (i.e., read/write characteristics) of a magnetic head and also test the electromagnetic wave durability of the magnetic head, which means that it is possible to efficiently carry out reliable tests. Also, in addition to investigating whether products are defective or non-defective, it is possible to use the testing apparatus according to the present invention to investigate the electromagnetic wave durability of magnetic heads at the design stage of the magnetic heads and feedback the test results into the design of the magnetic heads.

### Second Embodiment

FIG. 2 shows the construction of a second embodiment of a testing apparatus for a magnetic head according to the present invention. The testing apparatus according to the present embodiment differs to the first embodiment in that a parabola antenna 40 is provided to focus the electromagnetic waves emitted from the electromagnetic wave generating apparatus 30 onto the magnetic head. According to the present embodiment, by focusing the electromagnetic waves on the magnetic head using the parabola antenna 40, it is possible to cause the electromagnetic waves to effectively act upon the magnetic head, which makes it possible to reliably test the electromagnetic wave durability of the magnetic head.

When the electromagnetic wave durability of a magnetic head is tested by emitting electromagnetic waves toward the magnetic head using the parabola antenna 40, the method of using the testing apparatus is the same as that described in the first embodiment.

Note that the method of focusing the electromagnetic waves from the electromagnetic wave generating apparatus 30 onto the magnetic head is not limited to a method that uses the parabola antenna 40 and it is also possible to focus the electromagnetic waves using a suitable antenna.

When emitting electromagnetic waves onto a magnetic head from the electromagnetic wave generating apparatus 30 to test the electromagnetic wave durability of the magnetic head, since there will be fluctuations in the testing precision if external electromagnetic waves are allowed to penetrate, it is possible to shield the testing environment of the testing apparatus composed of the electromagnetic wave generating apparatus 30 and the magnetic head to be tested using a shield and thereby remove the effects of such external disturbances.

Also, when the testing environment of the present testing apparatus is shielded using a shield, there is the advantage that it is possible to prevent electromagnetic waves from the electromagnetic wave generating apparatus 30 from leaking to the outside.

Note that in the embodiment described above, the electromagnetic conversion characteristics and electromagnetic wave durability of a magnetic head were tested with the head assembly 13, where the slider 10 has been mounted on the head suspension 12, supported on the setting portion 14. However, there is also a method that tests the electromagnetic conversion characteristics of a magnetic head by setting an individual slider, which is not mounted on a head suspension as described above, on a testing apparatus with an air-bearing structure and recording and playing back a signal using a recording medium. The method and apparatus for testing a magnetic head according to the present invention can also be applied to such an apparatus that tests individual sliders.

What is claimed is:

1. A testing apparatus for a magnetic head that tests electromagnetic conversion characteristics of the magnetic head by causing the magnetic head to fly above a surface of a recording medium and testing recording and playback characteristics of the magnetic head for the recording medium,
wherein the testing apparatus comprises:
a setting portion that moves the magnetic head to and supports the magnetic head at a position where the magnetic head is loaded on the recording medium and a position where the magnetic head is withdrawn from the load position;
an electromagnetic wave emitting device that emits electromagnetic waves toward the magnetic head; and
a detector that is electrically connected to the magnetic head and detects an output signal of the magnetic head.

2. A testing apparatus for a magnetic head according to claim 1,
further comprising an antenna that focuses the electromagnetic waves emitted by the electromagnetic wave emitting device onto the magnetic head.

3. A testing apparatus for a magnetic head according to claim 1,
wherein a testing region that includes the electromagnetic wave emitting device is shielded by a shield from external electromagnetic waves.

4. A testing method for a magnetic head that uses a testing apparatus according to claim 1 and comprises steps of:
supporting the magnetic head using the setting portion;
moving the magnetic head to the position that is withdrawn from the load position on the recording medium;
emitting electromagnetic waves toward the magnetic head from the electromagnetic wave emitting device at the moved-to position; and
testing electromagnetic wave durability of the magnetic head by detecting output noise of the magnetic head during emission of the electromagnetic waves using the detector.

5. A testing method for a magnetic head that uses a testing apparatus according to claim 1 and comprises steps of:
supporting the magnetic head using the setting portion;
moving the magnetic head to the load position on the recording medium;
emitting electromagnetic waves toward the magnetic head from the electromagnetic wave emitting device at the moved-to position; and
testing electromagnetic wave durability of the magnetic head by detecting output noise of the magnetic head during emission of the electromagnetic waves using the detector.

6. A testing method for a magnetic head according to claim 5,
wherein the magnetic head is supported at a varying flying height from a surface of the recording medium by the setting portion to detect flying-height-dependent electromagnetic wave durability of the magnetic head.

7. A testing method for a magnetic head according to claim 4,
wherein the electromagnetic wave durability of the magnetic head is tested by emitting electromagnetic waves from the electromagnetic wave emitting device toward the magnetic head while continuously varying the frequency and detecting output noise of the magnetic head using the detector.

8. A testing method for a magnetic head according to claim 5,
wherein the electromagnetic wave durability of the magnetic head is tested by emitting electromagnetic waves from the electromagnetic wave emitting device toward the magnetic head while continuously varying the frequency and detecting output noise of the magnetic head using the detector.

9. A testing method for a magnetic head according to claim 4,
wherein electromagnetic wave durability of the magnetic head is tested with a head assembly, where a slider has been mounted on a head suspension, set on the setting portion.

10. A testing method for a magnetic head according to claim 5,
wherein electromagnetic wave durability of the magnetic head is tested with a head assembly, where a slider has been mounted on a head suspension, set on the setting portion.
